(19) United States
(12) Patent Application Publication
(10) Pub. No.: US 2025/0109978 A1
(43) Pub. Date: Apr. 3, 2025

(54) WEIGHT AND/OR LAYER THICKNESS MEASURING EQUIPMENT AND SUBSTRATE PROCESSING SYSTEMS AND METHODS INCLUDING SUCH EQUIPMENT

(71) Applicant: ASM IP Holding B.V., Almere (NL)

(72) Inventor: Salam Harb, Scottsdale, AZ (US)

(21) Appl. No.: 18/898,765

(22) Filed: Sep. 27, 2024

Related U.S. Application Data
(60) Provisional application No. 63/541,495, filed on Sep. 29, 2023.

(51) Int. Cl. G01G 3/13; G01B 7/06

(52) U.S. Cl. CPC G01G 3/13; G01B 7/063

(57) ABSTRACT

Weight and/or layer thickness measurement systems include: (a) a support base for supporting an object; (b) an oscillator source applying oscillating frequency to the support base; (c) a strain sensor measuring strain induced in the support base by the oscillation; and (d) a phase locked loop module connected to the oscillator source and strain sensor. The oscillating frequency applied to the support base is modified based on phase difference information determined by the phase locked loop module to locate a resonant frequency for the support base and supported object. The resonant frequencies before and after processing are used to determine weight and/or thickness of a layer on the object. Cluster type substrate processing systems may include weight and/or layer thickness measurement systems, e.g., of these types, within a substrate handling chamber and/or in a separate chamber or station engaged with the substrate handling chamber.

### CROSS-REFERENCE TO RELATED APPLICATION(S)

This application claims the benefit of U.S. Provisional Application 63/541,495 filed on Sep. 29, 2023, the entire contents of which are incorporated herein by reference.

### FIELD OF THE DISCLOSURE

Some aspects of the present disclosure relate generally to weight and/or layer thickness measurement systems, e.g., that use resonant frequencies to determine the weight of an object (e.g., a layer applied to a substrate) and/or thickness of a layer deposited on an object. Additional or alternative aspects of this technology relate to systems and methods for determining weight and/or thickness of a layer applied to a substrate or removed from a substrate, e.g., during layer deposition and/or etching processes.

### BACKGROUND OF THE DISCLOSURE

Material layers are commonly deposited onto substrates during fabrication of semiconductor devices, such as during fabrication of integrated circuits and electronic devices. Material layer deposition generally is accomplished by supporting a substrate within a substrate processing chamber arrangement, heating the substrate to a desired deposition temperature, and flowing one or more material layer precursor gases through the chamber arrangement and across the substrate. As the precursor gas flows across the substrate, the material layer progressively develops onto the surface of the substrate, typically according to the temperature of the substrate and environmental conditions within the chamber arrangement.

In cluster type semiconductor vacuum processing tools, multiple substrate processing chambers may be coupled with a single substrate handling chamber that moves substrates into and out of the substrate processing chambers and into and out of the overall substrate processing system. Such systems allow multiple substrates to be processed simultaneously using common equipment provided in the substrate handling chamber.

Integrated circuit fabrication also includes steps of etching material layers formed on a substrate to remove material at selected locations. Such etching steps typically include applying a mask to a substrate and removing material not covered by the mask, e.g., using etchant liquids or gas, plasma, etc.

Integrated circuits are very small, and thus the amount of material applied during a layer deposition step and/or removed during an etching step typically is very small. Nonetheless, it is important that precise amounts of material be applied or removed, to assure that the final integrated circuit product will operate and function in the desired manner. Because the layer deposition steps typically take place within complicated systems (e.g., “cluster” type substrate processing systems as described above) under high temperature and very low pressure processing conditions, it can take significant time for a manufacturer to discover if one or more substrate processing steps and/or substrate processing chambers are not functioning properly. In conventional substrate processing systems, to determine thickness of a layer on a substrate, the processed substrate has to be removed from the system and measured using stand-alone film thickness metrology like ellipsometry. This process is very slow. If there is an issue with a manufacturing step and/or a substrate processing chamber, a significant number of faulty products may be produced before the issue is discovered, resulting in significant waste and increased costs.

Also, in conventional systems, layer thickness measurements can be performed only on limited sample of substrates to prevent throughput impact on the process line.

In other situations, researchers and engineers may use Quartz Crystal Microbalance (QCM) techniques to measure film thickness on coupons. But this method only is effective during development of a recipe—not on a production and/or high-volume manufacturing (HVM) line.

While conventional semiconductor production systems and methods generally have been acceptable for their intended purpose, there is room for improvement. For example, earlier detection of potential issues with substrate processing chambers and/or methods that result in improper layer deposition and/or etching results would be welcome advances in the art.

### SUMMARY OF THE DISCLOSURE

Some aspects of this technology relate to weight and/or layer (e.g., film) thickness measurement systems that use resonant frequencies to determine the weight of an object (e.g., the weight of a layer (e.g., a film) applied to a substrate) and/or thickness of a layer (e.g., a film) on an object. Additional or alternative aspects of this technology relate to systems and methods for determining weight and/or thickness of a layer applied to a substrate or removed from a substrate, e.g., in an in-situ or in-line manner during layer deposition and/or etching processes and/or within the layer deposition and/or etching equipment or system. Additional or alternative aspects of this technology relate to cluster type substrate processing systems and methods that include metrology stations (e.g., layer weight and/or layer thickness measurement systems) within a substrate handling chamber and/or in a separate chamber or station engaged with the substrate handling chamber.

Weight and/or layer thickness measurement systems in accordance with at least some examples of this technology include one or more of: (a) a support base including a support surface for supporting an object to be weighed; (b) an oscillator source configured to apply an oscillating frequency to the support base; (c) a strain sensor configured to measure strain induced in the support base by the oscillator source; and/or (d) a phase locked loop module connected to the oscillator source and the strain sensor, wherein the oscillating frequency applied by the oscillator source to the support base is modified based on phase difference information determined by the phase locked loop module to locate a resonant frequency for the support base and any object supported by the support base.

In addition to one or more of the features described above, or as an alternative, weight and/or layer thickness measurement systems in accordance with at least some examples of this technology further may include one or more of: (i) a memory for storing data representing the resonant frequency; and/or (ii) a computer processing system programmed and adapted to: (a) receive input data representing a first resonant frequency determined for the support base and a first object supported thereon, (b) receive input data representing a second resonant frequency determined for the support base and a second object supported thereon, and (c) determine a weight difference between (1) the support base and the second object supported thereon and (2) the support base and the first object supported thereon based on the second resonant frequency and the first resonant frequency.

In addition to one or more of the features described above, or as an alternative, in at least some examples of this technology, the support base and the first object supported thereon will comprise a substrate prior to a layer deposition process; the support base and the second object supported thereon will comprise the substrate after the layer deposition process, wherein the substrate includes a layer deposited thereon.

In addition to one or more of the features described above, or as an alternative, in at least some examples of this technology, the computer processing system further will be programmed and adapted to determine a thickness of the layer based on the weight difference between (i) the support base and the second object supported thereon and (ii) the support base and the first object supported thereon.

In addition to one or more of the features described above, or as an alternative, in at least some examples of this technology, the oscillator source will comprise a piezoelectric resonator, and the strain sensor will comprise a piezoelectric strain sensor.

Substrate processing systems in accordance with at least some examples of this technology include one or more of: (A) a first substrate handling chamber including a first plurality of component mounting regions, the first plurality of component mounting regions including: (i) a first load-lock module mounting region configured to engage a first load-lock module and through which incoming substrates for processing are received and outgoing substrates that have been processed are discharged, (ii) a second load-lock module mounting region, (iii) a first plurality of substrate processing chamber mounting regions, and (iv) a metrology station mounting region; (B) a load-lock module connected with the second load-lock module mounting region; (C) a second substrate handling chamber including a second plurality of component mounting regions, the second plurality of component mounting regions including: (i) a third load-lock module mounting region engaged with the load-lock module and (ii) a second plurality of substrate processing chamber mounting regions; and/or (D) a metrology station connected with the metrology station mounting region, the metrology station configured to measure at least one of weight of a substrate, weight of a layer on a substrate, or layer thickness on a substrate.

In addition to one or more of the features described above, or as an alternative, in at least some examples of this technology, the metrology station will be configured to: (a) determine a first resonant frequency of a support base and a substrate to be weighed supported on the support base prior to processing the substrate in a substrate processing chamber, (b) determine a second resonant frequency of the support base and the substrate supported on the support base after the processing, and (c) determine a weight difference for the substrate after processing and before processing based on the second resonant frequency and the first resonant frequency.

In addition to one or more of the features described above, or as an alternative, in at least some examples of this technology, the metrology station further will be configured to determine a thickness of a layer applied to the substrate during the processing based on the weight difference.

In addition to one or more of the features described above, or as an alternative, in at least some examples of this technology, the metrology station will comprise one or more of: (A) a support base including a support surface for supporting a substrate to be weighed; (B) an oscillator source configured to apply an oscillating frequency to the support base; (C) a strain sensor configured to measure strain induced in the support base by the oscillator source; and/or (D) a phase locked loop module connected to the oscillator source and the strain sensor, wherein the oscillating frequency applied by the oscillator source to the support base is modified based on phase difference information determined by the phase locked loop module to locate a resonant frequency for the support base and the substrate supported by the support base.

In addition to one or more of the features described above, or as an alternative, in at least some examples of this technology, the metrology station will comprise one or more of: (A) a memory for storing data representing the resonant frequency, and/or (B) a computer processing system programmed and adapted to: (i) receive input data representing a first resonant frequency determined for the support base and a first substrate supported thereon, (ii) receive input data representing a second resonant frequency determined for the support base and a second substrate supported thereon, and (iii) determine a weight difference between (1) the support base and the second substrate supported thereon and (2) the support base and the first substrate supported thereon based on the second resonant frequency and the first resonant frequency.

In addition to one or more of the features described above, or as an alternative, in at least some examples of this technology, the support base and the first substrate supported thereon will comprise a substrate prior to a layer deposition process, and the support base and the second substrate supported thereon will comprise the substrate after the layer deposition process, wherein the second substrate includes a layer deposited thereon.

In addition to one or more of the features described above, or as an alternative, in at least some examples of this technology, the computer processing system further will be programmed and adapted to determine a thickness of the layer based on the weight difference between (i) the support base and the second substrate supported thereon and (ii) the support base and the first substrate supported thereon.

In addition to one or more of the features described above, or as an alternative, in at least some examples of this technology, the support base and the first substrate supported thereon will comprise a substrate prior to an etching process, the support base and the second substrate supported thereon will comprise the substrate after the etching process, wherein the second substrate includes a layer that has been etched.

In addition to one or more of the features described above, or as an alternative, in at least some examples of this technology, the oscillator source will comprise a piezoelectric resonator and the strain sensor will comprise a piezoelectric strain sensor.

Substrate processing systems in accordance with at least some examples of this technology include one or more of: (A) a first substrate handling chamber including: (i) a first facet configured to receive incoming substrates for processing and for discharging substrates that have been processed, (ii) a second facet extending at an oblique angle with respect to the first facet, the second facet being configured to engage a first substrate processing chamber, (iii) a third facet extending at an oblique angle with respect to the first facet, the third facet being configured to engage a second substrate processing chamber, (iv) a fourth facet extending at an oblique angle with respect to the second facet, (v) a fifth facet extending at an oblique angle with respect to the third facet, and (vi) a sixth facet connected between the fourth facet and the fifth facet; (B) a load-lock module connected with the sixth facet; (C) a second substrate handling chamber including: (i) a seventh facet connected with the load-lock module, (ii) an eighth facet extending at an oblique angle with respect to the seventh facet, the eighth facet being configured to engage a third substrate processing chamber, (iii) a ninth facet extending at an oblique angle with respect to the seventh facet, the ninth facet being configured to engage a fourth substrate processing chamber, (iv) a tenth facet extending at an oblique angle with respect to the eighth facet, the tenth facet being configured to engage a fifth substrate processing chamber, and (v) an eleventh facet extending at an oblique angle with respect to the ninth facet, the eleventh facet being configured to engage a sixth substrate processing chamber, wherein the load-lock module includes one or more substrate supports for holding substrates being transferred between the first substrate handling chamber and the second substrate handling chamber through the sixth facet and the seventh facet; and/or (D) a metrology station for measuring at least one of weight of a substrate, weight of a layer on a substrate, or layer thickness on a substrate, wherein the metrology station is attached to one of the fourth facet or the fifth facet.

In addition to one or more of the features described above, or as an alternative, in at least some examples of this technology, the metrology station will be attached to the fourth facet, and the substrate processing system will further comprise a second metrology station for measuring at least one of weight of a substrate, weight of a layer on a substrate, or layer thickness on a substrate attached to the fifth facet.

Substrate processing systems in accordance with at least some examples of this technology include one or more of: (A) a first substrate handling chamber including an interior chamber and a first robotic arm mounted within the interior chamber; (B) a first substrate processing chamber coupled with the first substrate handling chamber via a first gate valve, wherein a portion of the first robotic arm is configured to extend through the first gate valve and into the first substrate processing chamber to move substrates into and out of the first substrate processing chamber; and/or (C) a weight and/or layer thickness measurement system located within the interior chamber.

In addition to one or more of the features described above, or as an alternative, in at least some examples of this technology, the weight and/or layer thickness measurement system will be configured to: (a) determine a first resonant frequency of a support base and a substrate to be weighed supported on the support base prior to processing the substrate in the first substrate processing chamber, (b) determine a second resonant frequency of the support base and the substrate supported on the support base after processing the substrate in the first substrate processing chamber, and (c) determine a weight difference for the substrate after processing and before processing in the first substrate processing chamber based on the second resonant frequency and the first resonant frequency.

In addition to one or more of the features described above, or as an alternative, in at least some examples of this technology, the weight and/or layer thickness measurement system further will be configured to determine a thickness of a layer applied to the substrate while processing in the first substrate processing chamber based on the weight difference.

In addition to one or more of the features described above, or as an alternative, in at least some examples of this technology, the weight and/or layer thickness measurement system will comprise: (A) a support base including a support surface for supporting a substrate to be weighed; (B) an oscillator source configured to apply an oscillating frequency to the support base; (C) a strain sensor configured to measure strain induced in the support base by the oscillator source; and (D) a phase locked loop module connected to the oscillator source and the strain sensor, wherein the oscillating frequency applied by the oscillator source to the support base is modified based on phase difference information determined by the phase locked loop module to locate a resonant frequency for the support base and the substrate supported by the support base.

In addition to one or more of the features described above, or as an alternative, in at least some examples of this technology, the weight and/or layer thickness measurement system further will comprise: (A) a memory for storing data representing the resonant frequency, and (B) a computer processing system programmed and adapted to: (a) receive input data representing a first resonant frequency determined for the support base and a first substrate supported thereon, (b) receive input data representing a second resonant frequency determined for the support base and a second substrate supported thereon, and (c) determine a weight difference between (i) the support base and the second substrate supported thereon and (ii) the support base and the first substrate supported thereon based on the second resonant frequency and the first resonant frequency.

In addition to one or more of the features described above, or as an alternative, in at least some examples of this technology, the support base and the first substrate supported thereon will comprise a substrate prior to a layer deposition process, and the support base and the second substrate supported thereon will comprise the substrate after the layer deposition process, wherein the second substrate includes a layer deposited thereon.

In addition to one or more of the features described above, or as an alternative, in at least some examples of this technology, the computer processing system further will be programmed and adapted to determine a thickness of the layer based on the weight difference between (i) the support base and the second substrate supported thereon and (ii) the support base and the first substrate supported thereon.

In addition to one or more of the features described above, or as an alternative, in at least some examples of this technology, the oscillator source will comprise a piezoelectric resonator and the strain sensor will comprise a piezoelectric strain sensor.

In addition to one or more of the features described above, or as an alternative, substrate processing systems in accordance with at least some examples of this technology further will comprise a second substrate processing chamber coupled with the first substrate handling chamber via a second gate valve, wherein the portion of the first robotic arm is configured to extend through the second gate valve and into the second substrate processing chamber to move substrates into and out of the second substrate processing chamber, and wherein the first robotic arm is movable to move substrates: (a) between the weight and/or layer thickness measurement system and the first substrate processing chamber and (b) between the weight and/or layer thickness measurement system and the second substrate processing chamber.

In addition to one or more of the features described above, or as an alternative, substrate processing systems in accordance with at least some examples of this technology further will comprise a plurality of additional substrate processing chambers coupled with the first substrate handling chamber, wherein the portion of the first robotic arm is configured to extend into each of the plurality of additional substrate processing chambers to move substrates into and out of the additional substrate processing chambers, and wherein the first robotic arm is movable to move substrates: (a) between the weight and/or layer thickness measurement system and the first substrate processing chamber and (b) between the weight and/or layer thickness measurement system and each of the additional substrate processing chambers.

Methods of determining weight and/or thickness of a layer on a substrate in accordance with at least some examples of this technology may comprise one or more of: (a) placing a substrate on a support surface of a support base; (b) applying oscillating frequency to the support base with the substrate supported thereon; (c) adjusting the oscillating frequency applied to the support base to locate a first resonant frequency for the support base with the substrate supported on the support surface; (d) processing the substrate to add a material layer to the substrate or to remove material from a layer on the substrate to thereby form a processed substrate; (e) placing the processed substrate on the support surface of the support base; (f) applying oscillating frequency to the support base with the processed substrate supported thereon; (g) adjusting the oscillating frequency applied to the support base to locate a second resonant frequency for the support base with the processed substrate supported thereon; and/or (h) determining at least one of a weight or a thickness of a layer on the processed substrate based on the second resonant frequency and the first resonant frequency.

In addition to one or more of the features described above, or as an alternative, methods in accordance with at least some examples of this technology further will comprise one or more of: (a) placing a reference substrate having a known weight on the support surface of the support base; (b) applying oscillating frequency to the support base with the reference substrate supported thereon; (c) adjusting the oscillating frequency applied to the support base with the reference substrate supported thereon to locate a reference resonant frequency; and/or (d) using the reference resonant frequency and the known weight for calibration and/or for selecting an initial oscillation frequency for a measurement.

In addition to one or more of the features described above, or as an alternative: (A) the steps of placing the substrate on the support surface of the support base and placing the processed substrate on the support surface of the support base include moving the substrate and the processed substrate using a first robotic arm; (B) prior to the processing of the substrate, the first robotic arm moves the substrate from the support surface of the support base to a substrate processing chamber that is coupled with a substrate handling chamber that includes the support base; and (C) after the processing of the substrate, the first robotic arm moves the substrate from the substrate processing chamber to the support surface of the support base located in the substrate handling chamber.

In addition to one or more of the features described above, or as an alternative, the steps of applying oscillating frequency to the support base with the substrate supported thereon and applying oscillating frequency to the support base with the processed substrate supported thereon include vibrating the support base using a piezoelectric resonator.

In addition to one or more of the features described above, or as an alternative, the steps of adjusting the oscillating frequency applied to the support base to locate the first resonant frequency and adjusting the oscillating frequency applied to the support base to locate the second resonant frequency include: measuring strain induced in the support base by a piezoelectric strain sensor, determining a phase difference between the oscillating frequency and responsive frequency detected by the piezoelectric strain sensor using a phase locked loop system, and adjusting the oscillating frequency until the phase difference measured by the phase locked loop system is about −90 degrees.

This Summary is provided to introduce a selection of concepts relating to this technology in a simplified form. These concepts are described in further detail in the Detailed Description below. This Summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 schematically illustrates a substrate processing system including a metrology station in accordance with some examples of this technology;

FIGS. 2A-2E provide various views of a metrology station and features of its use in substrate processing in accordance with some examples of this technology;

FIG. 3 provides a flow chart generally describing features of methods in accordance with some examples of this technology;

FIG. 4 provides a flow chart describing more detailed examples and features of methods in accordance with some examples of this technology;

FIG. 5 provides a flow chart describing calibration and/or use of reference weights in accordance with some examples of this technology; and

FIG. 6 schematically illustrates a substrate processing system including one or more metrology stations in accordance with some additional examples of this technology.

It will be appreciated that elements in the figures are illustrated for simplicity and clarity and have not necessarily been drawn to scale and/or with full detail. For example, the relative size of some of the elements in the figures may be exaggerated relative to other elements to help improve understanding of illustrated embodiments of the present disclosure.

### DETAILED DESCRIPTION

Reference now will be made to the drawings wherein like reference numerals identify similar structural features or aspects of the subject disclosure.

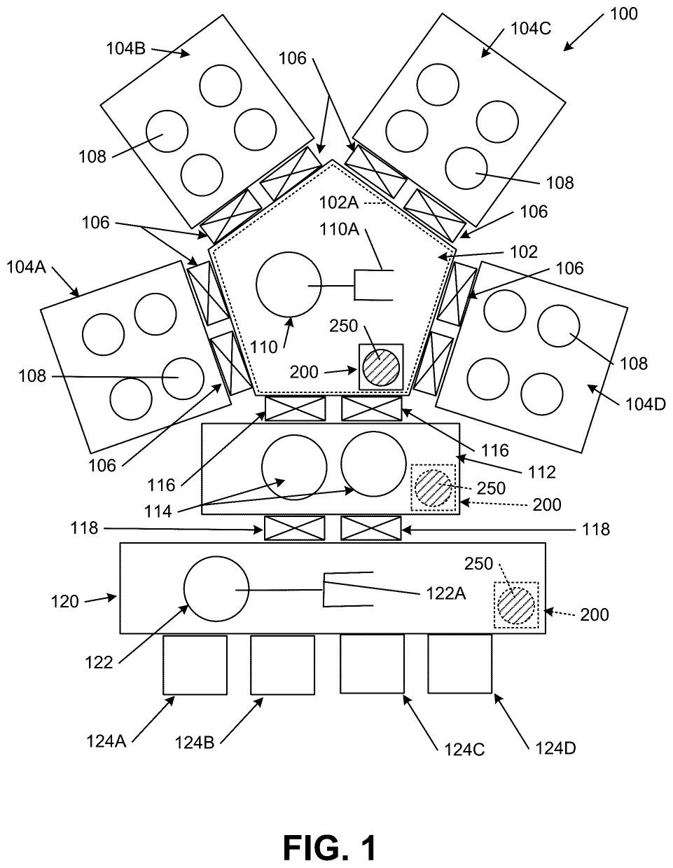

As noted above, material layers are commonly deposited onto substrates during fabrication of semiconductor devices, such as during fabrication of integrated circuits and electronic devices. FIG. 1 schematically illustrates a top view of a “cluster type” substrate processing system 100 in accordance with some examples of this technology. This example substrate processing system 100 includes a substrate handling chamber 102 that operatively connects with one to four substrate processing chambers 104A-104D via gate valves 106. Each substrate processing chamber 104A-104D includes one or more substrate supports 108 and is equipped to receive a substrate on the substrate support 108 and hold the substrate during processing (e.g., during material layer deposition as described above, etc.). FIG. 1 shows each substrate processing chamber 104A-104D including four substrate supports 108 onto which substrates can be placed during processing. More or fewer substrates supports 108 may be provided in each substrate processing chamber 104A-104D (e.g., the substrate processing chambers 104A-104D may be dual chamber modules (DCM) or quad chamber modules (QCM)). Substrate processing chambers 104A-104D in accordance with some examples of this technology may include another four substrate supports 108 located vertically beneath the four substrate supports 108 shown in the top view of FIG. 1. Each of the substrate processing chambers 104A-104D may have the same structures or one or more of the substrate processing chambers 104A-104D may have a different structure from other substrate processing chambers 104A-104D present.

The substrate handling chamber 102 includes robotic arm 110 used to move substrates into and out of the various substrate processing chambers 104A-104D through the gate valves 106. In use, a gate valve 106 is opened, an end effector 110A of the robotic arm 110 extends through the open gate valve 106 to insert a substrate into or remove a substrate from an interior chamber of the substrate processing chamber 104A-104D (e.g., placing a substrate on or taking a substrate off a substrate support 108 within the substrate processing chamber 104A-104D). Once the robotic arm 110 is retracted from the substrate processing chamber 104A-104D, the gate valve 106 is closed, thereby sealing the substrate processing chamber 104A-104D from the substrate handling chamber 102. Then, other desired actions can take place in the substrate processing chamber 104A-104D (e.g., material layer deposition, etc.) and/or the substrate handling chamber 102.

FIG. 1 further shows that this example substrate processing system 100 includes a load-lock module 112. The load-lock module 112 is connected with the substrate handling chamber 102 by one or more gate valves 116. The load-lock module 112 includes substrate holding components 114 (e.g., “setplates,” two shown in FIG. 1) for holding substrates on the way into the substrate handling chamber 102 for further processing and on the way out of the substrate handling chamber 102 (after processing is complete). The end effector 110A of robotic arm 110 moves through the gate valve 116 (when opened) to move substrates from the load-lock module 112 into the substrate handling chamber 102 (for layer deposition and/or other processing) and from the substrate handling chamber 102 into the load-lock module 112 (after processing is completed). The load-lock module 112 and gate valve(s) 116 keep the substrates isolated from the environment of the substrate handling chamber 102 until the conditions (e.g., temperature, pressure, content of atmosphere, etc.) within the substrate handling chamber 102 are ready for the substrate(s) to be inserted or removed, e.g., while waiting for all gate valves 106 to be closed.

The load-lock module 112 further is coupled with an equipment front end module 120 via one or more additional gate valves 118. The equipment front end module 120 includes a robotic arm 122. The end effector 122A of that robotic arm 122 moves through the gate valve(s) 118 (when opened) to move substrates from the equipment front end module 120 into the load-lock module 112 (for layer deposition and/or other processing) and from the load-lock module 112 into the equipment front end module 120 (after processing is completed). The robotic arm 122 of the equipment front end module 120 also picks up new substrates for processing from one of the load ports 124A-124D and returns processed substrates to one of the load ports 124A-124D, e.g., to be transported to another location for further processing or other action.

FIG. 1 further shows that the substrate handling chamber 102 of this example includes a metrology station 200. This metrology station 200 includes equipment for weighing substrates 250, e.g., before processing in one or more of substrate processing chambers 104A-104D and/after processing in one or more of substrate processing chambers 104A-104D. By weighing a substrate 250 before and after processing, one can determine the weight of a layer of material applied to the substrate 250 (e.g., during layer deposition processes) and/or the weight of material removed from a substrate (e.g., during etching processes). From the weight change, one also can estimate the thickness of a layer of material applied to the substrate 250 (e.g., knowing the weight change, the density of the material applied, and the area to which the layer is applied on the substrate 250, one can estimate the thickness of the layer applied (e.g., assuming a constant thickness over the area of the substrate 250)). Thus, metrology station 200 may comprise a weight and/or layer thickness measurement system.

In accordance with this specific example of the present technology, the metrology station 200 is provided within the interior chamber 102A of the substrate handling chamber 102. In this manner, the substrate 250 can be weighed substantially immediately before entering and/or after leaving one of the substrate processing chambers 104A-104D. Taking weight measurements immediately after processing may enable a manufacturer to quickly recognize whether one (or more) of the substrate processing chambers 104A-104D and/or whether a process or procedure running in one (or more) of the substrate processing chambers 104A-104D is not performing in the manner intended or expected (and thereby may be producing unsuitable substrate products that may need to be scrapped). These features may enable the manufacturer to more quickly take corrective action, thereby reducing scrap and waste. Further, its location within the interior chamber 102A allows the metrology station 200 to be quickly used for substrates processed in any of the multiple substrate processing chambers 104A-104D of this cluster type substrate processing system 100. Alternatively, if desired, a metrology station 200 could be provided in the load-lock module 112, in the equipment front end module 120, and/or in place of one of the substrate processing chambers 104A-104D and/or more than one metrology station 200 may be provided. FIG. 1 shows some of these additional or alternative locations for a metrology station 200 in broken lines.

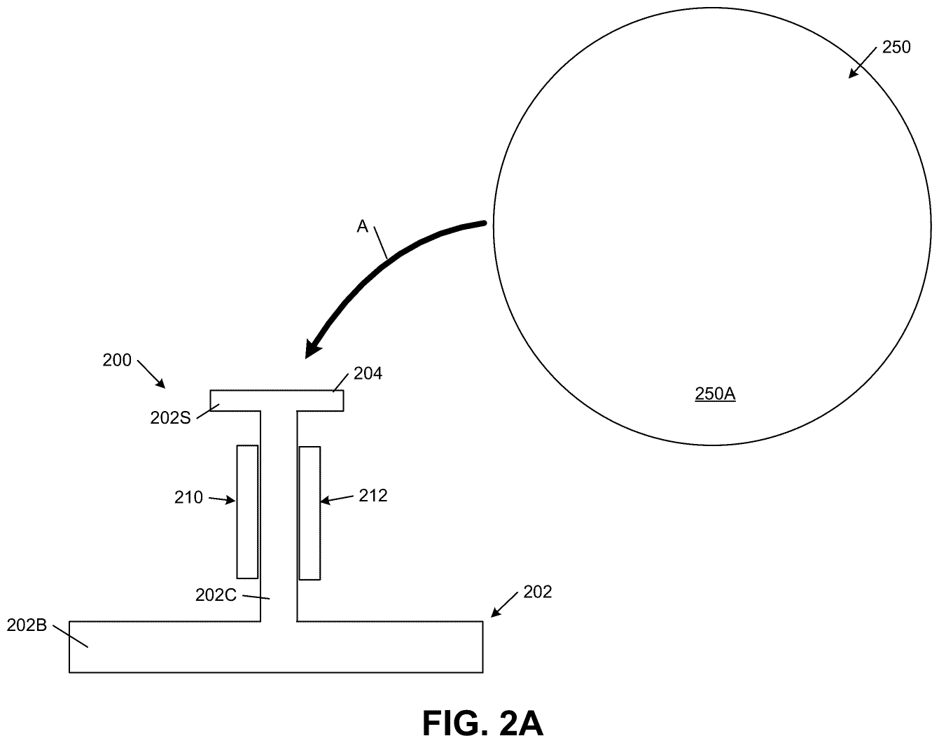

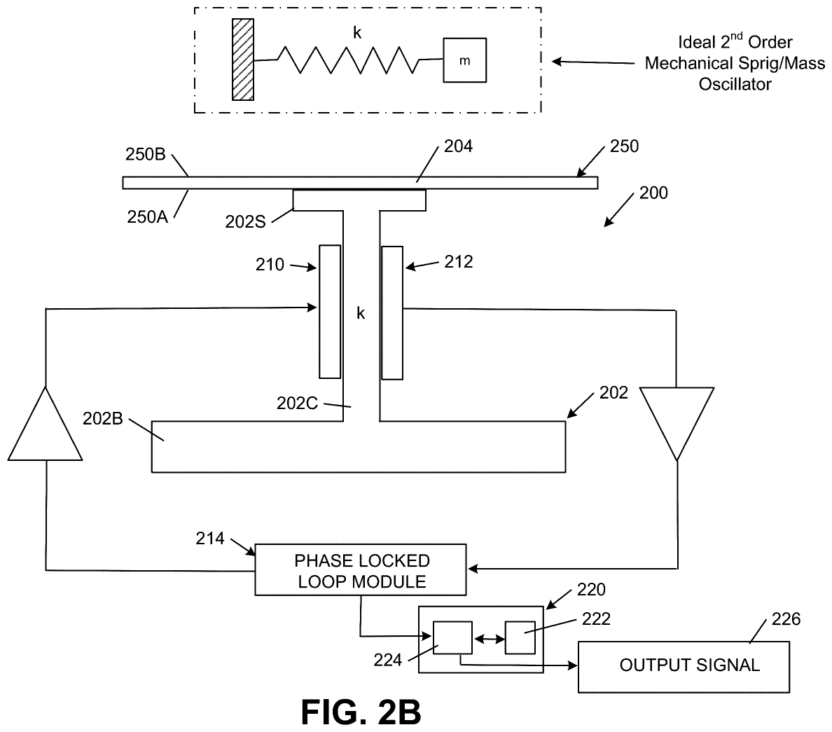

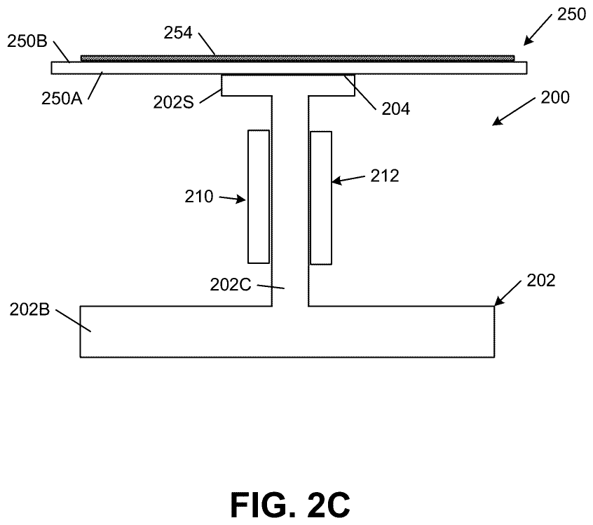

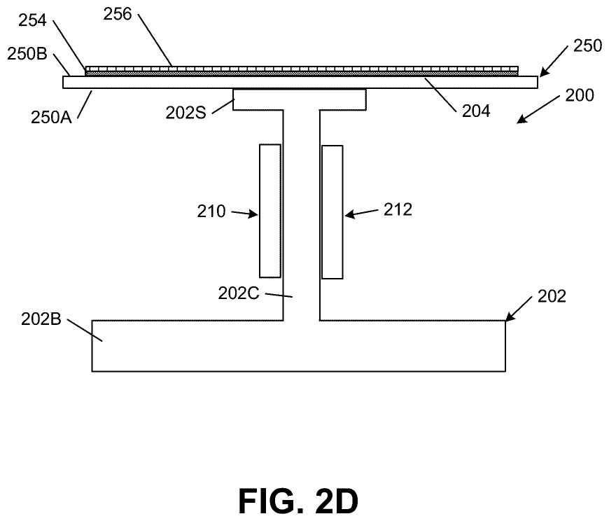

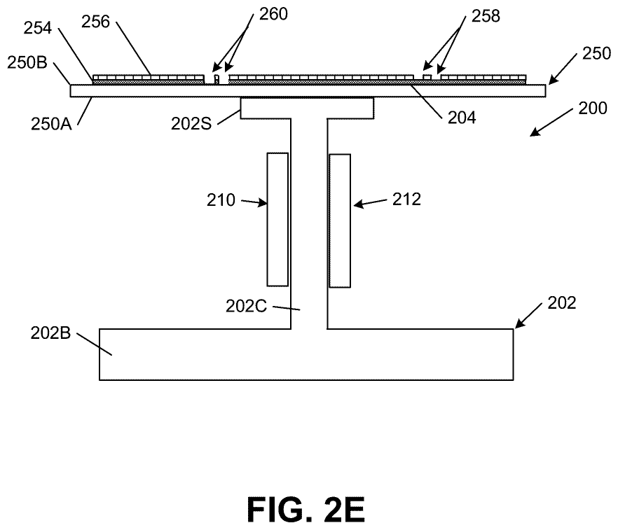

FIGS. 2A and 2B illustrate an example metrology station 200 for measuring weight and/or thickness of a layer of material applied to a substrate 250 in accordance with some examples of this technology. As shown in these figures, this example metrology station 200 includes a support base 202 that extends to form a support surface 204 for supporting an object (e.g., a substrate 250) to be weighed. The support base 202 of this example includes: (i) a base member 202B that may be supported on an interior bottom surface of the substrate handling chamber 102 (e.g., fixed to it by bolts or other fasteners), (ii) a cylindrical projection 202C (having any desired transverse cross sectional shape, such as square, circular elliptical, oval, rectangular, polygonal, etc.) extending upward from the base member 202B, and (iii) a support member 202S at the other end of the cylindrical projection 202C. A top surface of the support member 202S of this example forms or is engaged with the support surface 204. In some examples of this technology, the overall support base 202 (e.g., the base member 202B, the cylindrical projection 202C, and the support member 202S, including support surface 204) may be formed as a single, unitary, one-piece construction (e.g., by casting, forging, machining, molding, printing, etc.). When making measurements, one major surface 250A of the substrate 250 is placed the support surface 204, e.g., as shown by arrow A in FIG. 2A and in FIG. 2B (with the opposite major surface 250B facing away from the support base 202). Robotic arm 110 may move substrates 250 from one of the substrate processing chambers 104A-104D or from the load-lock module 112 to the metrology station 200 (e.g., placing the substrate 250 on the support surface 204 of the support base 202).

FIGS. 2A and 2B further show that this example metrology station 200 includes an oscillator source 210 that is configured to apply a force at an oscillating frequency to the support base 202 (e.g., to the cylindrical projection 202C in this illustrated example). The oscillator source 210 may comprise a piezoelectric resonator, e.g., of types that are known and commercially available, or other type of system to induce mechanical resonance in support base 202 (e.g., a voice coil). The oscillator source 210 is used to apply an oscillating force to the support base 202 to cause the support base 202 (and the substrate 250 mounted thereon) to vibrate. By adjusting vibrational frequency produced by the oscillator source 210, one can locate a resonant frequency for the support base 202 and the substrate 250 mounted thereon. The “resonant frequency” referred to throughout this specification may refer to the fundamental (or lowest) resonant frequency for the structure being discussed.

The metrology station 200 of FIGS. 2A and 2B further includes a strain sensor 212 (e.g., a piezoelectric strain sensor as are known and commercially available or other type of sensor for measuring strain or displacement). This strain sensor 212 is configured to measure strain induced in the support base 202 (and substrate 250 mounted thereon) by the oscillator source 210 applying vibrational force to the support base 202. A phase locked loop module 214 is connected to the oscillator source 210 and the strain sensor 212. Phase locked loop modules 214 are conventionally known and are commercially available. Phase locked loop modules 214, as are known, generate an output signal having a phase that is related to the phase of an input signal. Thus, using the phase locked loop module 214 as shown in FIG. 2B, one can: (a) compare the phases of the signals detected by the strain sensor 212 and applied to the support base 202 by the oscillator source 210, and (b) adjust frequency applied to the support base 202 by the oscillator source 210 until the detected phase shift determined by the phase locked loop module 214 is −90°. A −90° phase shift corresponds to a resonant frequency for the support base 202 and the substrate 250 mounted thereon.

At resonant frequency, the phase shift is extremely sensitive and detectable using the phase locked loop module 214. In accordance with some aspects of this technology, a technique for measuring layer (e.g., film) thickness/mass applied to a substrate 250 is based on comparative frequency shift (Δf) between: (a) the resonant frequency of the support base 202 loaded with the substrate 250 before layer deposition or etching, and (b) the resonant frequency of the support base 202 loaded with the substrate 250 after layer deposition or etching. This measurement system can be modeled as an ideal second order dynamic mechanical spring/mass oscillator with high Q factor (low damping), e.g., with the model as shown in the dot-dash box at the top of FIG. 2B. In such a model:

$${f}_{n} = \frac{\sqrt{k / {M}_{eq}}}{2 π}$$

where: fₙ represents the resonant frequency;
   k represents the spring constant (representative of the stiffness of the support base 202);
   M_{eq} represents the mass being oscillated, i.e., the mass of the support base 202 (M₂₀₂)
   plus the mass of the substrate 250 (M₂₅₀) plus the mass of anything present on the substrate 250 (e.g., a layer of material, if any (M_{Layer}), i.e., M_{eq}=M₂₀₂+M₂₅₀+M_{Layer}).
Generally, adding a layer (e.g., film) of material to a substrate 250 will cause the resonant frequency fₙ of the support base 202 loaded with the substrate 250 to increase, while removing material (e.g., etching) will cause the resonant frequency fₙ of the support base 202 loaded with the substrate 250 to decrease. Thus, changes in mass on the substrate 250 (due to the addition or removal of material) result in changes in resonant frequency (Δf) that can be detected by direct measurement of frequency or phase shift. Thus:
   Δf=fₙ (after substrate 250 processing)−fₙ (before substrate 250 processing).
Because k is constant for the system, and M₂₀₂ and M₂₅₀ remain constant for the two measurements, the resonant frequency shift or change Δf observed before and after substrate 250 processing takes place correlates to a change in M_{Layer}, the mass of the layer on the substrate 250.

As noted above, because one knows the type of material deposited (including its density) and the area on the substrate 250 to which it has been applied, one can determine the mass added or subtracted from the substrate 250 and/or estimate the layer thickness. As a more specific example, for one substrate 250 configuration (a 300 mm diameter substrate 250), a 50 Å layer of molybdenum is known to weight about 4 mg. Thus, if a measured frequency shift results in a determination of a M_{Layer} change of 0.4 mg, one can estimate that the molybdenum layer thickness is about 5 Å thick on the substrate 250 (assuming a uniform thickness has been deposited).

Additional features of this example metrology station 200 are shown in FIG. 2B. As shown, output from the phase locked loop module 214 can be sent to a computing system 220. The computing system 220 includes a memory 222 for storing data, e.g., including: (a) data representing the determined resonant frequency of the support base 202 loaded with the substrate 250 before layer deposition or etching, and (b) data representing the determined resonant frequency of the support base 202 loaded with the substrate 250 after layer deposition or etching. The computing system 220 further may include a computer processing system 224 (e.g., including one or more microprocessors) programmed and adapted to: (a) receive input data representing a first resonant frequency determined for the support base 202 and a first object (e.g., a first substrate 250) supported thereon, (b) receive input data representing a second resonant frequency determined for the support base 202 and a second object (e.g., a second substrate 250) supported thereon, (c) determine a difference between the second resonant frequency and the first resonant frequency (e.g., in some examples), and/or (d) determine a weight difference between (i) the support base 202 and the second object (e.g., a substrate 250 after processing) supported thereon and (ii) the support base 202 and the first object (e.g., a substrate before processing) supported thereon based on the difference between the second resonant frequency and the first resonant frequency. The computer processing system 224 further may generate and send an output signal 226, e.g., to any desired type of output device and/or in any desired form or format and/or using any desired type of communications protocol.

FIGS. 2B-2E further illustrate features of processes in accordance with some examples of this technology. As described above, the determined resonant frequency change and/or weight difference information may correspond to a difference in weight between (a) the support base 202 and a substrate 250 supported thereon after a layer deposition process, and (b) the support base 202 and the same substrate 250 supported thereon prior to the layer deposition process (where the weight difference corresponds to a weight of a layer deposited on the substrate 250, e.g., in a substrate processing chamber 104A-104D as shown in FIG. 1). For example, FIG. 2C shows a substrate 250 mounted on the support surface 204 of support base 202 with a first layer 254 formed on the top major surface 250B. The substrate 250 and first layer 254 as shown in FIG. 2C may constitute: (a) a substrate 250 “after processing” as compared to the substrate 250 shown in FIG. 2B and (b) a substrate 250 “before processing” as compared to the substrate 250 shown in FIG. 2D. As shown in FIG. 2D, at that stage, this example substrate 250 has two layers 254 and 256 formed on it (with layer 256 formed over layer 254 in this illustrated example, e.g., in a substrate processing chamber 104A-104D as shown in FIG. 1). By determining the change in resonant frequencies between: (a) the support base 202 and substrate 250 combination at the stage shown in FIG. 2C and (b) the support base 202 and substrate 250 combination at the stage shown in FIG. 2B, the mass (and optionally thickness) of first layer 254 can be determined. By determining the change in resonant frequencies between: (a) the support base 202 and substrate 250 combination at the stage shown in FIG. 2D and (b) the support base 202 and substrate 250 combination at the stage shown in FIG. 2C, the mass (and optionally thickness) of second layer 256 can be determined.

In some examples of this technology, the determined resonant frequency change and/or weight difference information may correspond to a difference in weight between (a) the support base 202 and a substrate 250 supported thereon after an etching process, and (b) the support base 202 and the same substrate 250 supported thereon prior to the etching process (where the weight difference corresponds to a weight of a material removed from one or more layers on the substrate 250). As noted above, FIG. 2D shows a substrate 250 mounted on the support surface 204 of support base 202 with a first layer 254 formed on the top major surface 250B and a second layer 256 formed on the first layer 254. The substrate 250 with the first layer 254 and second layer 256 as shown in FIG. 2D may constitute a substrate 250 “before processing” as compared to the substrate 250 shown in FIG. 2E. As shown in FIG. 2E, at that stage and after some further processing, this example substrate 250 includes some etchings 258 removing portion(s) of second layer 256 and some etchings 260 removing portion(s) of both the first layer 254 and the second layer 256. By determining the change in resonant frequencies between: (a) the support base 202 and substrate 250 combination at the stage shown in FIG. 2E and (b) the support base 202 and substrate 250 combination at the stage shown in FIG. 2D, the mass of material removed in the etching step(s) can be determined.

In other examples of this technology, the determined resonant frequency change and/or weight difference information may correspond to a difference in weight between (a) the support base 202 and a first object (e.g., a first substrate 250), and (b) the support base 202 and a second object different from the first object (e.g., a second, different substrate 250).

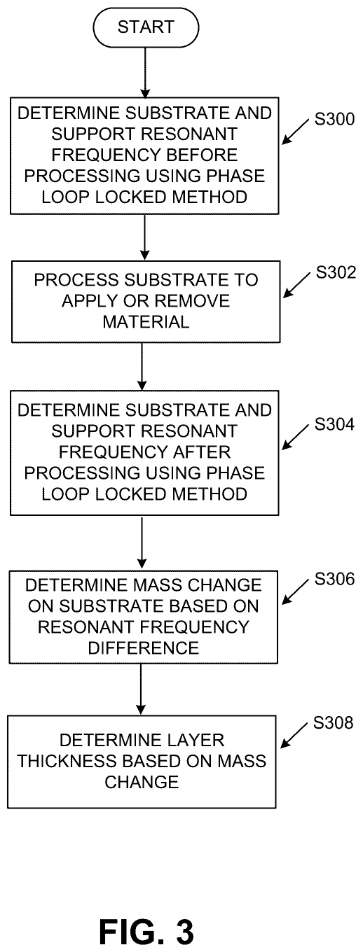

FIG. 3 provides additional details of methods of determining weight and/or thickness of a layer (e.g., layers 254, 256) on a substrate 250 in accordance with some examples of this technology. At Step S300, the resonant frequency is determined for a substrate 250 and support base 202 combination, e.g., at a metrology station 200. The substrate 250 at this stage may be fresh (i.e., with no layers deposited on it) or it may have one or more layers already deposited on it. This Step S300 uses the phase locked loop module 214 to find the resonant frequency by adjusting the oscillating frequency applied to substrate 250 and support base 202 combination until the phase locked loop module 214 registers a −90° phase shift between the frequency applied by oscillator source 210 and the measured frequency from the strain sensor 212. An oscillating frequency that induces a −90° phase shift detected by the phase locked loop module 214 corresponds to the resonant frequency for that support base 202 and substrate 250 combination.

At Step S302, the substrate 250 is placed in a substrate processing chamber (e.g., one of 104A-104D), and a layer deposition step or a material removal step (e.g., an etching step) takes place. This Step S302 will add mass to the substrate 250 (e.g., as a layer) or subtract mass from the substrate 250 (e.g., by etching material off the substrate 250). Once processing at Step S302 is complete, at Step S304, the substrate 250 with the modified surface is moved back to the metrology station 200 and the resonant frequency for this modified combination (modified substrate 250 on support base 202) is determined. This Step S304 again uses the phase locked loop module 214 to find the resonant frequency by adjusting the oscillating frequency applied to modified substrate 250 and support base 202 combination until the phase locked loop module 214 registers a −90° phase shift between the frequency applied by oscillator source 210 and the measured frequency from the strain sensor 212.

As described above, adding material to the substrate 250 or taking material away from the substrate 250 will result in a shift in the resonant frequency between the resonant frequency measured at Step S300 (before substrate 250 processing) and the resonant frequency measured at Step S304 (after substrate 250 processing). This change in the resonant frequency correlates to a change in the mass of the structure being oscillated (i.e., the support base 202 and the substrate 250 supported by it). Because the support base 202 and substrate 250 itself do not change mass between Steps S300 and S304, the only mass change can be attributed to the material layer(s) deposited onto the substrate 250 at Step S302 or material removed (e.g., etched) from the substrate at Step S302. Thus, at Step S306, this method determines the mass change on the substrate 250 based on the change in measured resonant frequencies between Steps S300 and S304. Once the mass change on the substrate 250 is determined at Step S306, the layer thickness may be determined at Step S308, e.g., estimated based on the area of the layer deposited and the density of the material being deposited.

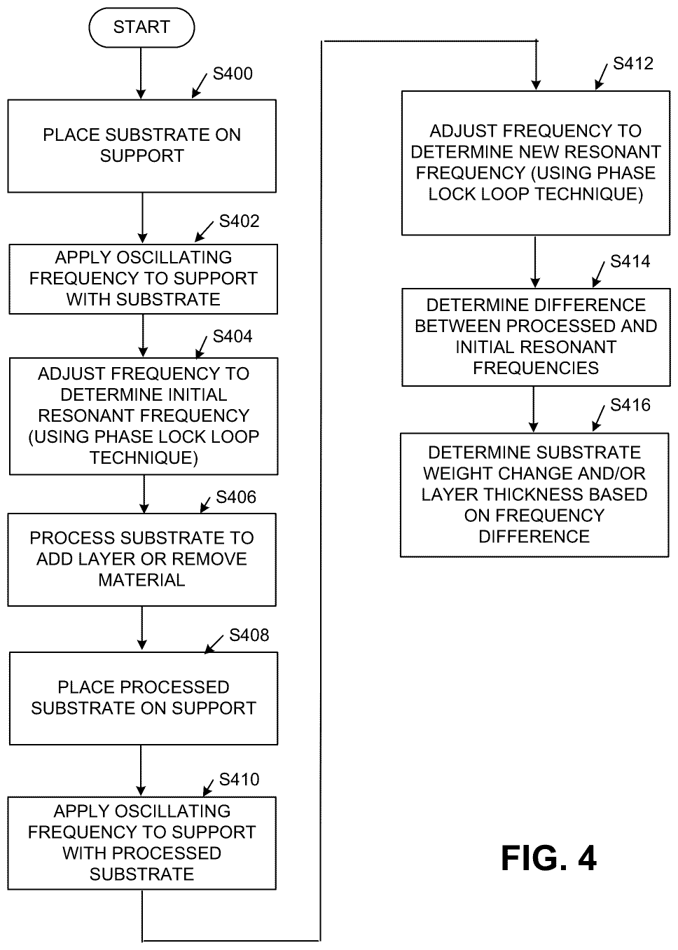

FIG. 4 provides additional details of methods in accordance with some examples of this technology, e.g., methods of determining weight and/or thickness of a layer (e.g., layers 254, 256) on a substrate 250. The description of FIG. 4 also refers back to structures described above in conjunction with FIGS. 1-2E. At Step S400, robotic arm 110 places a substrate 250 on a support surface 204 of a support base 202. The substrate 250 at this stage may be fresh (i.e., with no layers deposited on it) or it may have one or more layers already deposited on it. At Step S402, an oscillating frequency is applied to the support base 202 and substrate 250 combination by an oscillator source 210 (e.g., a piezoelectric resonator). Using the phase locked loop module 214 at Step S404, the oscillating frequency applied by the oscillator source 210 is adjusted until the resonant frequency is determined for this substrate 250 and support base 202 combination. The resonant frequency is determined as the frequency at which the phase locked loop module 214 registers a phase shift of −90° between the frequency applied by oscillator source 210 and the measured frequency at the strain sensor 212. The resonant frequency determined at Step S404 also will be referred to as a “first” resonant frequency in this discussion.

At Step S406, the substrate 250 is placed in a substrate processing chamber (e.g., one of 104A-104D) using robotic arm 110, and a layer deposition step (or a material removal step (e.g., an etching step)) takes place. This Step S406 will add mass to the substrate 250 (e.g., as a layer) or subtract mass from the substrate 250 (e.g., by etching material off the substrate 250). Once processing at Step S406 is complete, at Step S408, the substrate 250 with the modified surface is removed from the substrate processing chamber 104A-104D (or other processing location), moved back to the metrology station 200, and placed on support base 202 (using robotic arm 110). Then, at Step S410, an oscillating frequency is applied to the support base 202 holding the modified substrate 250 by oscillator source 210. Using the phase locked loop module 214 at Step S412, the oscillating frequency applied by the oscillator source 210 is adjusted until the resonant frequency is determined for this modified substrate 250 and support base 202 combination. Again, the resonant frequency is determined as the frequency at which the phase locked loop module 214 registers a phase shift of −90° between the frequency applied by oscillator source 210 and the measured frequency at the strain sensor 212. The resonant frequency determined at Step S412 also will be referred to as a “second” resonant frequency in this discussion. The difference in resonant frequency between the second resonant frequency (determined at Step S412) and the first resonant frequency (determined at Step S404) is determined at Step S414.

As described above, adding material to the substrate 250 typically will result in an increase in resonant frequency, i.e., the second resonant frequency (at Step S412) is expected to be somewhat higher than the first resonant frequency (measured at Step S404). Removing material from the substrate 250, on the other hand, typically will result in a decrease in resonant frequency, i.e., the second resonant frequency (at Step S412) is expected to be somewhat lower than the first resonant frequency (measured at Step S404). Changes in the resonant frequency correlate to changes in the mass of the structure being oscillated (i.e., the support base 202 and the substrate 250 supported by it). Because the support base 202 and substrate 250 themselves do not change mass between Steps S412 and S404, the only mass change can be attributed to the material layer(s) deposited on the substrate 250 at Step S406 or material removed (e.g., etched) from the substrate at Step S406. Thus, at Step S416, this method determines the mass change on the substrate 250 based on the change in measured resonant frequencies determined at Step S414. Once the mass change on the substrate 250 is determined, the layer thickness may be determined at Step S416, e.g., estimated based on the area of the layer deposited and the density of the material being deposited.

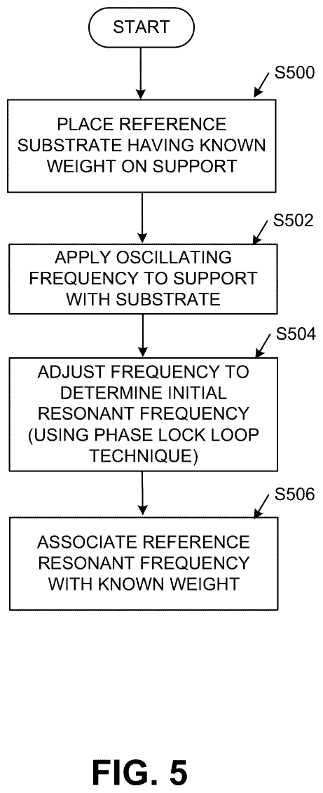

FIG. 5 illustrate methods of calibrating metrology stations 200 in accordance with aspects of this technology and/or creating a “lookup table” with information useful for metrology stations 200 and methods in accordance with aspects of this technology. In this method, at Step S500, a reference substrate having a known weight is placed on a support surface 204 of a support base 202 of metrology station 200 (e.g., as shown in FIGS. 2A and 2B). The metrology station 200 may be located in a substrate handling chamber 102 or at any other appropriate location. At Step S502, an oscillating frequency is applied to the support base 202 (with the reference substrate mounted thereon) by an oscillator source 210 (e.g., a piezoelectric resonator). Using the phase locked loop module 214 at Step S504, the oscillating frequency applied by the oscillator source 210 is adjusted until the resonant frequency is determined for this reference substrate and support base 202 combination. The resonant frequency is determined as the frequency at which the phase locked loop module 214 registers a phase shift of −90° between the frequency applied by oscillator source 210 and the measured frequency at the strain sensor 212. The resonant frequency determined at Step S504 is associated with the reference substrate of known weight at Step S506.

Using reference substrates of different known weights, data can be generated, e.g., for use as a “look up” table (e.g., to be stored in computer memory) with the resonant frequency information associated with a plurality of different substrate weights. Such data can enable systems and methods in accordance with at least some examples of this technology to determine mass differences associated with a layer deposited on a substrate or with an amount of material removed from a substrate (during etching) based on the change in resonant frequencies before and after the substrate processing method has taken place to add or remove material from the substrate. Additionally or alternatively, data of this type also can provide known combinations of associated mass and resonant frequency information that will allow systems and methods in accordance with some aspects of this technology to interpolate or extrapolate to estimate mass differences associated with resonant frequencies located between or near known combinations of associated mass and resonant frequency information.

Additionally or alternatively, use of a reference substrate in the method of FIG. 5 can be used along with the method of FIG. 4. More specifically, when a resonant frequency is found for a reference substrate close to the weight of the substrates 250 to be processed and weighed, information relating to that resonant frequency can be used as a starting point at Steps S402 and/or S410, which may help to “zero in” on the resonant frequency more quickly during Steps S404 and/or S412.

In the systems and methods described above, the metrology station 200 is provided in a substrate handling chamber 102 of a cluster type substrate processing system 100. Other configurations are possible. For example, as mentioned above, metrology stations of this type may be provided in the load-lock module 112, and/or in the equipment front end module 120, as shown in broken lines in FIG. 1. Metrology stations of this type also may be provided in place of one of the substrate processing chambers 104A-104D.

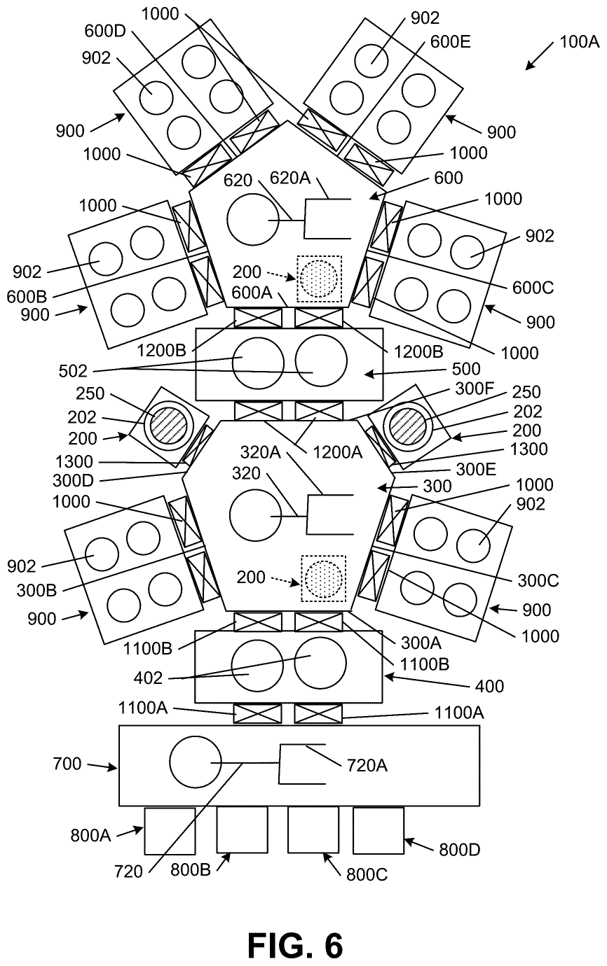

FIG. 6 illustrates another “cluster” type substrate processing system 100A in accordance with some examples of this technology. This substrate processing system 100A may be of the types described in U.S. Provisional Patent Appln. No. 63/524,272 filed Jun. 30, 2023 and entitled “Extended Substrate Processing Systems and Methods with Additional Processing Chamber Connectability.” U.S. Provisional Patent Appln. No. 63/524,272 is entirely incorporated herein by reference. Where the same reference number is used in FIG. 6 as used in any of FIGS. 1-2E, the same or similar part is being referenced, and much of the overlapping description may be omitted.

The substrate processing system 100A shown in FIG. 6 includes: (a) a first substrate handling chamber 300 (an “inboard” substrate handling chamber) including a first robotic arm 320 having an end effector 320A; (b) a first load-lock module 400 (an “inboard” load-lock module) connected at one edge or facet 300A of the first substrate handling chamber 300; (c) a second load-lock module 500 (an “outboard” load-lock module) connected at the opposite edge or facet 300F of the first substrate handling chamber 300; and (d) a second substrate handling chamber 600 (an “outboard” substrate handling chamber) including a second robotic arm 620 having an end effector 620A. The second load-lock module 500 extends between and connects the first substrate handling chamber 300 and the second substrate handling chamber 600. The first load-lock module 400 of this example also is connected with an equipment front end module 700 that includes a third robotic arm 720 having an end effector 720A. The equipment front end module 700 may include or connect with a nitrogen gas source for providing a nitrogen gas atmosphere within the equipment front end module 700. The equipment front end module 700 receives new substrates for processing into the substrate processing system 100A and discharges processed substrates from the substrate processing system 100A via one or more loading ports 800A-800D (moving the substrates between the loading port(s) 800A-800D and the first load-lock module 400 using the robotic arm 720). While four loading ports 800A-800D are shown in the example of FIG. 6, more or fewer loading ports may be provided in other examples of this technology.

Each of the first substrate handling chamber 300 and the second substrate handling chamber 600 includes plural substrate processing chamber mounting regions (e.g., at exposed facets 300A-300F and 600A-600E around their sides) and is connected with (or connectable to) multiple substrate processing chambers 900. The example of FIG. 6 shows two substrate processing chambers 900 connected with facets 300B and 300C of substrate handling chamber 300 and four substrate processing chambers 900 connected with facets 600B-600E of substrate handling chamber 600. Substrates are transferred into the substrate processing chambers 900 where one or more layers of material are deposited onto a surface of the substrate and/or other desired substrate processing takes place. FIG. 6 shows each substrate processing chamber 900 including four substrate supports 902 onto which substrates can be placed during processing. More or fewer substrates supports 902 may be provided in each substrate processing chamber 900 (e.g., the substrate processing chambers 900 may be dual chamber modules (DCM) or quad chamber modules (QCM)). Substrate processing chambers 900 in accordance with some examples of this technology may include another four substrate supports 902 located vertically beneath the four substrate supports 902 shown in the top view of FIG. 6. Each of the substrate processing chambers 900 may have the same structures or one or more of the substrate processing chambers 900 may have a different structure from other of the substrate processing chambers 900 present.

Each of the first substrate handling chamber 300 and the second substrate handling chamber 600 is connected with its respective substrate processing chambers 900 via one or more gate valves 1000. While two gate valves 1000 are shown connecting substrate handling chambers 300, 600 with each of their respective substrate processing chambers 900, more or fewer gate valves 1000 may be provided with each substrate processing chamber 900, in other examples of this technology. Substrate processing chambers 900 in accordance with some examples of this technology may be connected with their respective substrate handling chamber 300, 600 by another two gate valves 1000, e.g., located vertically beneath the two gate valves 1000 shown in the top view of FIG. 6. When closed, the gate valves 1000 sealingly separate the substrate handling chambers 300, 600 from their respective substrate processing chambers 900 (so that independent atmospheric conditions may be maintained in each chamber). When open, the gate valves 1000 provide an opening (e.g., a substrate transfer slot) through which the end effector 320A, 620A of a robotic arm 320, 620 can extend to move substrates into and out of the substrate processing chamber 900. The openings through the gate valves 1000 align with substrate transfer slots provided in the substrate processing chambers 900 and the substrate handling chambers 300, 600, to enable substrates to be moved between the substrate processing chambers 900 and the substrate handling chambers 300, 600 through the gate valves 1000. Each of gate valves 1000 may have the same structure or one or more of the gate valves 1000 may have a different structure from other gate valves 1000 present.

One face of the first load-lock module 400 connects with the equipment front end module 700 by one or more gate valves 1100A (two shown in FIG. 6), and the opposite face of the first load-lock module 400 connects with the first substrate handling chamber 300 by one or more gate valves 1100B (two shown in FIG. 6). The first load-lock module 400 further includes one or more substrate supports 402 (two shown in FIG. 5, e.g., “setplates”) for holding substrates while they wait to be moved into the equipment front end module 700 or the first substrate handling chamber 300. When closed, the gate valves 1100A, 1100B sealingly separate the load-lock module 400 from the equipment front end module 700 and the substrate handling chamber 300 (so that independent atmospheric conditions may be maintained in each chamber). When open, the gate valves 1100A provide an opening (e.g., a substrate transfer slot) through which the end effector 720A of robotic arm 720 can extend to move substrates into and out of the equipment front end module 700. The openings through the gate valves 1100A align with substrate transfer slots provided in the equipment front end module 700 and the first load-lock module 400 to enable substrates to be moved between the equipment front end module 700 and the first load-lock module 400 through gate valves 1100A. When open, the gate valves 1100B provide an opening (e.g., a substrate transfer slot) through which the end effector 320A of robotic arm 320 can extend to move substrates into and out of the substrate handling chamber 300. The openings through the gate valves 1100B align with substrate transfer slots provided in the substrate handling chamber 300 and the first load-lock module 400 to enable substrates to be moved between the substrate handling chamber 300 and the first load-lock module 400 through gate valves 1100B. Each of gate valves 1100A, 1100B may have the same structure or one or more of the gate valves 1100A, 1100B may have a different structure from other gate valves 1000, 1100A, 1100B present.

In the substrate processing system 100A of FIG. 6, one face of the second load-lock module 500 connects with the first substrate handling chamber 300 by one or more gate valves 1200A (two shown in FIG. 6), and the opposite face of the second load-lock module 500 connects with a load-lock mounting region provided with the second substrate handling chamber 600 by one or more gate valves 1200B (two shown in FIG. 6). The second load-lock module 500 further includes one or more substrate supports 502 (two shown in FIG. 6, e.g., “setplates”) for holding substrates while they wait to be moved between the two substrate handling chambers 300, 600. When closed, the gate valves 1200A, 1200B sealingly separate the second load-lock module 500 from the two substrate handling chambers 300, 600 (so that independent atmospheric conditions may be maintained in each chamber). When open, the gate valves 1200A provide an opening (e.g., a substrate transfer slot) through which the end effector 320A of robotic arm 320 can extend to move substrates into and out of the first substrate handling chamber 300. The openings through the gate valves 1200A align with substrate transfer slots provided in the first substrate handling chamber 300 and the second load-lock module 500 to enable substrates to be moved between the substrate handling chamber 300 and the second load-lock module 500 through gate valves 1200A. When open, the gate valves 1200B provide an opening (e.g., a substrate transfer slot) through which the end effector 620A of robotic arm 620 can extend to move substrates into and out of the second substrate handling chamber 600. The openings through the gate valves 1200B align with substrate transfer slots provided in the second substrate handling chamber 600 and the second load-lock module 500 to enable substrates to be moved between the second substrate handling chamber 600 and the second load-lock module 500 through gate valves 1200B. Each of gate valves 1200A, 1200B may have the same structure or one or more of the gate valves 1200A, 1200B may have a different structure from other gate valves 1200A, 1200B present. Gate valves 1200A and/or 1200B also may have the same or different structures from gate valves 1000, 1100A, and/or 1100B.

The first load-lock module 400 may have the same structure as the second load-lock module 500 and/or the first and second load-lock modules 400, 500 may be interchangeable (e.g., so that load-lock modules 400, 500 can switch positions and/or have a modular structure). In other examples, the first load-lock module 400 and the second load-lock module 500 may have different structures and/or may not be interchangeable (e.g., so that load-lock modules 400, 500 cannot switch positions in the substrate processing system 100A). Either or both load-lock modules 400, 500 may be multi-station cooling capable and/or path through types.

FIG. 6 further shows that either or both of the substrate handling chambers 300, 600 may include a metrology station 200, e.g., of the types described above. These metrology stations 200, when present, may have any of the structures, functions, and/or features described above in conjunction with FIGS. 1-5, including any options or alternatives for those structures, functions, and/or features described above.

Additionally or alternatively, the example substrate processing system 100A of FIG. 6 includes other potential arrangements for metrology stations 200 in accordance with some examples of this technology. FIG. 6 shows the inboard substrate handling chamber 300 including six facets (e.g., arranged in a hexagonal shape from the top view shown in FIG. 6). As described above: (a) one facet 300A provides a load-lock mounting region (and is engaged with the first load-lock module 400 via gate valves 1100B in this illustrated example), (b) the opposite facet 300F provides a second load-lock mounting region (and is engaged with the second load-lock module 500 via gate valves 1200A in this example), and (c) two of the facets (facets 300B and 300C located closest to the first load-lock module 400 in this example) provide substrate processing chamber mounting regions (and are connected with substrate processing chambers 900 in this example). Each of those four facets are relatively wide, e.g., able to accommodate at least two gate valves (and at least two substrate transfer slots) in their width (or side-to-side) direction.

This illustrated substrate handling chamber 300, however, includes two additional facets (facets 300D and 300E located closest to the second load-lock module 500 in this example). These two additional facets 300D and 300E have a smaller width (in the side-to-side direction) than facets 300A-300C and 300F (e.g., potentially accommodating one substrate transfer slot in the width direction). In this illustrated example, at least one of these two facets 300D, 300E provides a metrology station mounting region such that the substrate handling chamber 300 may be engaged with (or may be constructed as) a metrology station 200. The metrology station(s) 200 may be configured to measure and/or determine at least one of weight of a substrate, weight of a layer on a substrate, and/or thickness of a layer on a substrate. The metrology station(s) 200 associated with facets 300D and/or 300E in this example may include at least some of the structures shown in FIGS. 2A-2E contained in a separate chamber that is attached to (and potentially isolatable from) the substrate handling chamber 300, e.g., via a gate valve 1300. In the example of FIG. 6, each of facets 300D and 300E is engaged with or constructed as a metrology station 200. The metrology station(s) 200 provided at facets 300D and/or 300E may have any of the structures, functions, and/or features described above in conjunction with FIGS. 1-5, including any options or alternatives for those structures, functions, and/or features described above.

As some more specific features, this example inboard substrate handling chamber 300 includes: (a) the first facet 300A configured to receive incoming substrates 250 for processing and for discharging substrates 250 that have been processed, (b) the second facet 300B extending at an oblique angle with respect to the first facet 300A and configured to engage a substrate processing chamber 900, (c) the third facet 300C extending at an oblique angle with respect to the first facet 300A and configured to engage another substrate processing chamber 900, (d) the fourth facet 300D extending at an oblique angle with respect to the second facet 300B, (e) the fifth facet 300E extending at an oblique angle with respect to the third facet 300C, and (f) the sixth facet 300F connected between the fourth facet 300D and the fifth facet 300E. The sixth facet 300F may extend at oblique angles with respect to the fourth facet 300D and/or the fifth facet 300E. Robotic arm 320 may move substrates 250 into and out of the metrology station(s) 200, e.g., through aligned substrate transfer slots provided in the metrology station 200 chamber(s), the gate valve(s) 1300, and the substrate handling chamber 300 at facet(s) 300D and/or 300E.

As some further features, the outboard load-lock module 500 in this example substrate processing system 100A is connected with the sixth facet 300F (e.g., via gate valves 1200A). The outboard substrate handling chamber 600 includes five facets (e.g., arranged in a pentagonal shape from the top view shown in FIG. 6). In this illustrated example, the outboard substrate handling chamber 600 includes: (a) a seventh facet 600A connected with the outboard load-lock module 500 (via gate valve(s) 1200B), (b) an eighth facet 600B extending at an oblique angle with respect to the seventh facet 600A and configured to engage a substrate processing chamber 900, (c) a ninth facet 600C extending at an oblique angle with respect to the seventh facet 600A and configured to engage another substrate processing chamber 900, (d) a tenth facet 600D extending at an oblique angle with respect to the eighth facet 600B and configured to engage another substrate processing chamber 900, and (e) an eleventh facet 600E extending at an oblique angle with respect to the ninth facet 600C and configured to engage another substrate processing chamber 900. The tenth facet 600D and eleventh facet 600E may extend from one another at an oblique angle. Outboard load-lock module 500 includes one or more substrate supports 502 for holding substrates 250 being transferred between the first substrate handling chamber 300 and the second substrate handling chamber 600 through the sixth facet 300F and the seventh facet 600A.

In accordance with at least some aspects of the present technology, providing one or more metrology stations 200 within the substrate processing system 100, 100A has various advantages. Using this technology, substrates 250 can be weighed very soon before entering and/or after leaving one of the substrate processing chambers 104A-104D and without leaving the controlled environment of the substrate processing system 100, 100A. These features allow weights to be taken, e.g., before the substrate 250 is exposed to oxygen, water, and/or other potential contaminants that may deposit on the substrate surface. Thus, more accurate weight and/or thickness measurements may be taken (which is advantageous because the layers and/or weights being measured typically are quite small). This technology also may enable a manufacturer to quickly recognize whether one (or more) of the substrate processing chambers 104A-104D, 900 and/or whether a process or procedure running in one (or more) of the substrate processing chambers 104A-104D, 900 is not performing in the manner intended or as expected (and thereby may be producing unsuitable substrate products that may need to be scrapped). These features may enable the manufacturer to more quickly take corrective action, thereby reducing scrap and waste.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A weight and/or layer thickness measurement system, comprising:
a support base including a support surface for supporting an object to be weighed;
an oscillator source configured to apply an oscillating frequency to the support base;
a strain sensor configured to measure strain induced in the support base by the oscillator source; and
a phase locked loop module connected to the oscillator source and the strain sensor, wherein the oscillating frequency applied by the oscillator source to the support base is modified based on phase difference information determined by the phase locked loop module to locate a resonant frequency for the support base and any object supported by the support base.

2. The weight and/or layer thickness measurement system according to claim 1, further comprising:
a memory for storing data representing the resonant frequency; and
a computer processing system programmed and adapted to: (a) receive input data representing a first resonant frequency determined for the support base and a first object supported thereon, (b) receive input data representing a second resonant frequency determined for the support base and a second object supported thereon, and (c) determine a weight difference between (i) the support base and the second object supported thereon and (ii) the support base and the first object supported thereon based on the second resonant frequency and the first resonant frequency.

3. The weight and/or layer thickness measurement system according to claim 2, wherein the support base and the first object supported thereon comprise a substrate prior to a layer deposition process, wherein the support base and the second object supported thereon comprise the substrate after the layer deposition process, and wherein the substrate includes a layer deposited thereon.

4. The weight and/or layer thickness measurement system according to claim 3, wherein the computer processing system is further programmed and adapted to determine a thickness of the layer based on the weight difference between (i) the support base and the second object supported thereon and (ii) the support base and the first object supported thereon.

5. The weight and/or layer thickness measurement system according to claim 1, wherein the oscillator source comprises a piezoelectric resonator, and wherein the strain sensor comprises a piezoelectric strain sensor.

6. A substrate processing system, comprising:
a first substrate handling chamber including a first plurality of component mounting regions, the first plurality of component mounting regions including: (a) a first load-lock module mounting region configured to engage a first load-lock module and through which incoming substrates for processing are received and outgoing substrates that have been processed are discharged, (b) a second load-lock module mounting region, (c) a first plurality of substrate processing chamber mounting regions, and (d) a metrology station mounting region;
a load-lock module connected with the second load-lock module mounting region;
a second substrate handling chamber including a second plurality of component mounting regions, the second plurality of component mounting regions including: (a) a third load-lock module mounting region engaged with the load-lock module and (b) a second plurality of substrate processing chamber mounting regions; and
a metrology station connected with the metrology station mounting region, the metrology station configured to measure at least one of weight of a substrate, weight of a layer on a substrate, or layer thickness on a substrate.

7. The substrate processing system according to claim 6, wherein the metrology station is configured to: (a) determine a first resonant frequency of a support base and a substrate to be weighed supported on the support base prior to processing the substrate in a substrate processing chamber, (b) determine a second resonant frequency of the support base and the substrate supported on the support base after the processing, and (c) determine a weight difference for the substrate after processing and before processing based on the second resonant frequency and the first resonant frequency.

8. The substrate processing system according to claim 7, wherein the metrology station further is configured to determine a thickness of a layer applied to the substrate during the processing based on the weight difference.

9. The substrate processing system according to claim 6, wherein the metrology station comprises:
a support base including a support surface for supporting a substrate to be weighed;
an oscillator source configured to apply an oscillating frequency to the support base;
a strain sensor configured to measure strain induced in the support base by the oscillator source; and
a phase locked loop module connected to the oscillator source and the strain sensor, wherein the oscillating frequency applied by the oscillator source to the support base is modified based on phase difference information determined by the phase locked loop module to locate a resonant frequency for the support base and the substrate supported by the support base.

10. The substrate processing system according to claim 9, wherein the metrology station further comprises:
a memory for storing data representing the resonant frequency, and
a computer processing system programmed and adapted to: (a) receive input data representing a first resonant frequency determined for the support base and a first substrate supported thereon, (b) receive input data representing a second resonant frequency determined for the support base and a second substrate supported thereon, and (c) determine a weight difference between (i) the support base and the second substrate supported thereon and (ii) the support base and the first substrate supported thereon based on the second resonant frequency and the first resonant frequency.

11. The substrate processing system according to claim 10, wherein the support base and the first substrate supported thereon comprises a substrate prior to a layer deposition process, wherein the support base and the second substrate supported thereon comprises the substrate after the layer deposition process, and wherein the second substrate includes a layer deposited thereon.

12. The substrate processing system according to claim 11, wherein the computer processing system further is programmed and adapted to determine a thickness of the layer based on the weight difference between (i) the support base and the second substrate supported thereon and (ii) the support base and the first substrate supported thereon.

13. The substrate processing system according to claim 10, wherein the support base and the first substrate supported thereon comprises a substrate prior to an etching process, wherein the support base and the second substrate supported thereon comprises the substrate after the etching process, and wherein the second substrate includes a layer that has been etched.

14. The substrate processing system according to claim 9, wherein the oscillator source comprises a piezoelectric resonator, and wherein the strain sensor comprises a piezoelectric strain sensor.

15. A substrate processing system, comprising:
a first substrate handling chamber including:
(a) a first facet configured to receive incoming substrates for processing and for discharging substrates that have been processed,
(b) a second facet extending at an oblique angle with respect to the first facet, the second facet being configured to engage a first substrate processing chamber,
(c) a third facet extending at an oblique angle with respect to the first facet, the third facet being configured to engage a second substrate processing chamber,
(d) a fourth facet extending at an oblique angle with respect to the second facet,
(e) a fifth facet extending at an oblique angle with respect to the third facet, and
(f) a sixth facet connected between the fourth facet and the fifth facet;
a load-lock module connected with the sixth facet;
a second substrate handling chamber including:
(a) a seventh facet connected with the load-lock module,
(b) an eighth facet extending at an oblique angle with respect to the seventh facet, the eighth facet being configured to engage a third substrate processing chamber,
(c) a ninth facet extending at an oblique angle with respect to the seventh facet, the ninth facet being configured to engage a fourth substrate processing chamber,
(d) a tenth facet extending at an oblique angle with respect to the eighth facet, the tenth facet being configured to engage a fifth substrate processing chamber, and
(e) an eleventh facet extending at an oblique angle with respect to the ninth facet, the eleventh facet being configured to engage a sixth substrate processing chamber,
wherein the load-lock module includes one or more substrate supports for holding substrates being transferred between the first substrate handling chamber and the second substrate handling chamber through the sixth facet and the seventh facet; and
a metrology station for measuring at least one of weight of a substrate, weight of a layer on a substrate, or layer thickness on a substrate, wherein the metrology station is attached to one of the fourth facet or the fifth facet.

16. The substrate processing system according to claim 15, wherein the metrology station is attached to the fourth facet, and wherein the substrate processing system further comprises:
a second metrology station for measuring at least one of weight of a substrate, weight of a layer on a substrate, or layer thickness on a substrate, wherein the second metrology station is attached to the fifth facet.

17. A substrate processing system, comprising:
a first substrate handling chamber including an interior chamber and a first robotic arm mounted within the interior chamber;
a first substrate processing chamber coupled with the first substrate handling chamber via a first gate valve, wherein a portion of the first robotic arm is configured to extend through the first gate valve and into the first substrate processing chamber to move substrates into and out of the first substrate processing chamber; and
a weight and/or layer thickness measurement system located within the interior chamber.

18. The substrate processing system according to claim 17, wherein the weight and/or layer thickness measurement system is configured to: (a) determine a first resonant frequency of a support base and a substrate to be weighed supported on the support base prior to processing the substrate in the first substrate processing chamber, (b) determine a second resonant frequency of the support base and the substrate supported on the support base after processing the substrate in the first substrate processing chamber, and (c) determine a weight difference for the substrate after processing and before processing in the first substrate processing chamber based on the second resonant frequency and the first resonant frequency.

19. The substrate processing system according to claim 18, wherein the weight and/or layer thickness measurement system is further configured to determine a thickness of a layer applied to the substrate while processing in the first substrate processing chamber based on the weight difference.

20. The substrate processing system according to claim 17, wherein the weight and/or layer thickness measurement system comprises:
a support base including a support surface for supporting a substrate to be weighed;
an oscillator source configured to apply an oscillating frequency to the support base;
a strain sensor configured to measure strain induced in the support base by the oscillator source; and
a phase locked loop module connected to the oscillator source and the strain sensor, wherein the oscillating frequency applied by the oscillator source to the support base is modified based on phase difference information determined by the phase locked loop module to locate a resonant frequency for the support base and the substrate supported by the support base.

21. The substrate processing system according to claim 20, wherein the weight and/or layer thickness measurement system further comprises:
a memory for storing data representing the resonant frequency, and
a computer processing system programmed and adapted to: (a) receive input data representing a first resonant frequency determined for the support base and a first substrate supported thereon, (b) receive input data representing a second resonant frequency determined for the support base and a second substrate supported thereon, and (c) determine a weight difference between (i) the support base and the second substrate supported thereon and (ii) the support base and the first substrate supported thereon based on the second resonant frequency and the first resonant frequency.

22. The substrate processing system according to claim 21, wherein the support base and the first substrate supported thereon comprise a substrate prior to a layer deposition process, wherein the support base and the second substrate supported thereon comprise the substrate after the layer deposition process, and wherein the second substrate includes a layer deposited thereon.

23. The substrate processing system according to claim 22, wherein the computer processing system further is programmed and adapted to determine a thickness of the layer based on the weight difference between (i) the support base and the second substrate supported thereon and (ii) the support base and the first substrate supported thereon.

24. The substrate processing system according to claim 20, wherein the oscillator source comprises a piezoelectric resonator, and wherein the strain sensor comprises a piezoelectric strain sensor.

25. The substrate processing system according to claim 17, further comprising:
a second substrate processing chamber coupled with the first substrate handling chamber via a second gate valve, wherein the portion of the first robotic arm is configured to extend through the second gate valve and into the second substrate processing chamber to move substrates into and out of the second substrate processing chamber, and wherein the first robotic arm is movable to move substrates: (a) between the weight and/or layer thickness measurement system and the first substrate processing chamber and (b) between the weight and/or layer thickness measurement system and the second substrate processing chamber.

26. The substrate processing system according to claim 17, further comprising:
a plurality of additional substrate processing chambers coupled with the first substrate handling chamber, wherein the portion of the first robotic arm is configured to extend into each of the plurality of additional substrate processing chambers to move substrates into and out of the additional substrate processing chambers, and wherein the first robotic arm is movable to move substrates: (a) between the weight and/or layer thickness measurement system and the first substrate processing chamber and (b) between the weight and/or layer thickness measurement system and each of the additional substrate processing chambers.

27. A method of determining weight and/or thickness of a layer on a substrate, comprising:
placing a substrate on a support surface of a support base;
applying oscillating frequency to the support base with the substrate supported thereon;
adjusting the oscillating frequency applied to the support base to locate a first resonant frequency for the support base with the substrate supported on the support surface;
processing the substrate to add a material layer to the substrate or to remove material from a layer on the substrate to thereby form a processed substrate;
placing the processed substrate on the support surface of the support base;
applying oscillating frequency to the support base with the processed substrate supported thereon;
adjusting the oscillating frequency applied to the support base to locate a second resonant frequency for the support base with the processed substrate supported thereon; and
determining at least one of a weight or a thickness of a layer on the processed substrate based on the second resonant frequency and the first resonant frequency.

28. The method according to claim 27, further comprising:
placing a reference substrate having a known weight on the support surface of the support base;
applying oscillating frequency to the support base with the reference substrate supported thereon;
adjusting the oscillating frequency applied to the support base with the reference substrate supported thereon to locate a reference resonant frequency; and
using the reference resonant frequency and the known weight for calibration and/or for selecting an initial oscillation frequency for a measurement.

29. The method according to claim 27, wherein the steps of placing the substrate on the support surface of the support base and placing the processed substrate on the support surface of the support base include moving the substrate and the processed substrate using a first robotic arm;
wherein prior to the processing of the substrate, the first robotic arm moves the substrate from the support surface of the support base to a substrate processing chamber that is coupled with a substrate handling chamber that includes the support base; and
wherein after the processing of the substrate, the first robotic arm moves the substrate from the substrate processing chamber to the support surface of the support base located in the substrate handling chamber.

30. The method according to claim 27, wherein the steps of applying oscillating frequency to the support base with the substrate supported thereon and applying oscillating frequency to the support base with the processed substrate supported thereon include vibrating the support base using a piezoelectric resonator.

31. The method according to claim 30, wherein the steps of adjusting the oscillating frequency applied to the support base to locate the first resonant frequency and adjusting the oscillating frequency applied to the support base to locate the second resonant frequency include:
measuring strain induced in the support base by a piezoelectric strain sensor, determining a phase difference between the oscillating frequency and responsive frequency detected by the piezoelectric strain sensor using a phase locked loop system, and adjusting the oscillating frequency until the phase difference measured by the phase locked loop system is about −90 degrees.
